(19) United States
(12) Patent Application Publication
(10) Pub. No.: US 2026/0023124 A1
(43) Pub. Date: Jan. 22, 2026

(54) Fire Alarm Battery Load. Tester

(71) Applicant: Michael Bradley Ellis, St. Albert (CA)

(72) Inventor: Michael Bradley Ellis, St. Albert (CA)

(21) Appl. No.: 19/227,168

(22) Filed: Jun. 3, 2025

Related U.S. Application Data
(60) Provisional application No. 63/673,170, filed on Jul. 19, 2024.

(51) Int. Cl. G01R 31/385; G08B 29/04

(52) U.S. Cl. CPC G01R 31/386; G08B 29/043

(57) ABSTRACT

The present disclosure provides a fire alarm battery load tester. The fire alarm battery load tester includes a housing defining an interior space to enclose an electronic circuitry operable to test a fire alarm battery, and a fan to cool the electronic circuitry, and a set of test leads to connect the fire alarm battery load tester to the fire alarm battery. The housing further comprises a switch to reroute a current signal from the fire alarm battery to the electronic circuit, a display to display at least a voltage magnitude and a current magnitude associated with the fire alarm battery, and an indicator to indicate a reverse polarity of the fire alarm battery. The electronic circuitry includes one or more electronic components housed thereon, for example one or more resistors, one or more diodes, a voltmeter, an ammeter, and a relay.

### RELATED APPLICATIONS

This application claims benefit of U.S. Provisional Patent Application 63/673,170, filed on Jul. 19, 2024, the disclosure of which is hereby incorporated herein by reference in its entirety.

### BACKGROUND OF THE INVENTION

### Technical Field

The present disclosure generally relates to battery tester, and more particularly relates to a fire alarm battery load tester.

### Background

The new silent accelerated test method described according to the Underwriters Laboratories of Canadian standards CAN/ULC s536-19 for fire alarm systems is designed to ensure the reliability and performance of critical safety devices. Additionally, the silent accelerated test is also mentioned in CAN/ULC s537-19. The new silent accelerated test method involves using a 5 Ohm minimum 200-Watt resistor, a voltmeter and an ammeter to test fire alarm battery circuit under load conditions. The batteries must be under load conditions for 5 minutes, in this time if the voltage drops below 85 percent of the battery's listed voltage, the battery fails the test. In operation, such a test method may measure (for example, a flow of current and voltage) electrical properties of the fire alarm battery circuit under load conditions. The electrical properties are such as flow of current and voltage. The process is aimed at simulating real world scenarios to verify the fire alarm system battery robustness. However, the practical implementation of this method poses significant challenges particularly in the field settings.

Field technicians face difficulties due to need for two multimeters, that must be precisely connected to specific points in the fire alarm battery circuit. Additionally, the 5 Ohm minimum 200 W resistor generates substantial heat during the test, thereby making the components hot and potentially hazardous to handle. This not only complicates transportation and storage but also raises safety concerns for the field technicians who must manage the hot equipment and ensure accurate measurements. The technician also faces an arc flash hazard if the multimeters are connected incorrectly. These issues highlight the need for a more field friendly approach to perform the new silent accelerated test. Moreover, field technicians may be tempted to solve these problems by building their own testers that may create standardization issues.

### SUMMARY OF THE INVENTION

In order to solve the foregoing problem, the present disclosure may provide a portable fire alarm battery load tester having a fan to test fire alarm batteries.

In one aspect, a fire alarm battery load tester is provided. The fire alarm battery load tester may include a housing defining an interior space, and an electronic circuitry arranged inside the housing and operable to test a fire alarm battery. The fire alarm battery load tester also includes a set of test leads to connect the electronic circuitry to the fire alarm battery to direct an electric current from the fire alarm battery to the electronic circuitry to enable a measurement of one of more electrical parameters of the fire alarm battery. Moreover, the fire alarm battery load tester includes a fan coupled to the housing to cool the electronic circuitry.

In an embodiment, the fire alarm battery load tester includes a test switch to control a flow of electric current from the fire alarm battery to the electronic circuitry.

In an embodiment, the fire alarm battery load tester includes a display to show the one or more electrical parameters of the fire alarm battery measured by the electronic circuitry.

In an embodiment, the one or more electrical parameters includes a voltage of the fire alarm battery and a current of the fire alarm battery.

In an additional embodiment, the fire alarm battery load tester includes an indicator to indicate a reverse polarity of the fire alarm battery.

In an embodiment, the electronic circuitry includes one or more electronic components. The one or more electronic components includes at least one of one or more resistors, one or more diodes, or one or more relays.

In an embodiment, the fire alarm battery load tester includes a communication device to facilitate a sharing of data measured by the electronic circuitry to a smart phone.

In an embodiment, the fire alarm battery load tester includes magnets to allow it to be securely fastened to the fire alarm panel housing during testing.

In an embodiment, the communication device is a short range communication device.

In an embodiment, the fire alarm battery load tester includes a reverse polarity protector to electrically disconnect the fire alarm battery from the electronic circuitry in response to reverse polarity connection of the fire alarm battery with the fire alarm battery load tester.

In an embodiment, the fire alarm battery load tester includes a shutdown mechanism adapted to shut down the fire alarm battery load tester in response to an occurrence of a fault in the fire alarm battery load tester.

In an embodiment, the fire alarm battery load tester includes a timer to monitor a time duration since the fire alarm battery load tester is activated.

In an embodiment, the fire alarm battery load tester further includes a time delinquency shutdown switch communicatively coupled to the tester and is adapted to deactivate or shutdown the fire alarm battery load tester in response to determining idling of the fire alarm battery load tester for a predefined time duration.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF FIGURES

Having thus described example embodiments of the invention in general terms, reference will now be made to the accompanying drawings, which are not necessarily drawn to scale, and wherein:

FIG. 1 is a diagram that illustrates an exemplary network environment in which a fire alarm battery load tester is implemented, in accordance with an embodiment of the disclosure;

FIG. 2A illustrates an exemplary circuit diagram of the fire alarm battery load tester of FIG. 1, in accordance with an embodiment of the disclosure;

FIG. 2B illustrates another exemplary circuit diagram of the fire alarm battery load tester of FIG. 1, in accordance with an embodiment of the disclosure;

FIG. 3A illustrates a front view of an example fire alarm battery load tester, in accordance with an embodiment of the disclosure;

FIG. 3B illustrates a side view of the fire alarm battery load tester, in accordance with an embodiment of the disclosure;

FIG. 3C illustrates an internal view of a housing defining the interior space of the fire alarm battery load tester, in accordance with an embodiment of the disclosure;

FIG. 3D illustrates another exemplary internal view of the housing enclosing the electronic circuitry of the fire alarm battery load tester, in accordance with an embodiment of the disclosure;

FIG. 3E illustrates another example fire alarm battery load tester having at least one magnetic connector to enable a mounting to the fire alarm battery load tester to fire alarm chassis, in accordance with an embodiment of the disclosure; and

FIG. 4 is a flowchart that illustrates an exemplary method for fabricating the fire alarm battery load tester, in accordance with an embodiment of the disclosure.

### DETAILED DESCRIPTION

In the following description, for purposes of explanation, numerous specific details are set forth in order to provide a thorough understanding of the present disclosure. It will be apparent, however, to one skilled in the art that the present disclosure may be practiced without these specific details. In other instances, apparatus and methods are shown in block diagram form only in order to avoid obscuring the present disclosure.

Some embodiments of the present disclosure will now be described more fully hereinafter with reference to the accompanying drawings, in which some, but not all, embodiments of the disclosure are shown. Indeed, various embodiments of the disclosure may be embodied in many different forms and should not be construed as limited to the embodiments set forth herein; rather, these embodiments are provided so that this disclosure will satisfy applicable legal requirements. Like reference numerals refer to like elements throughout. Also, reference in this specification to “one embodiment” or “an embodiment” means that a particular feature, structure, or characteristic described in connection with the embodiment is included in at least one embodiment of the present disclosure. The appearance of the phrase “in one embodiment” in various places in the specification are not necessarily all referring to the same embodiment, nor are separate or alternative embodiments mutually exclusive of other embodiments. Further, the terms “a” and “an” herein do not denote a limitation of quantity, but rather denote the presence of at least one of the referenced items. Moreover, various features are described which may be exhibited by some embodiments and not by others. Similarly, various requirements are described which may be requirements for some embodiments but not for other embodiments. As used herein, the terms “data,” “content,” “information,” and similar terms may be used interchangeably to refer to data capable of being displayed, transmitted, received and/or stored in accordance with embodiments of the present disclosure. Thus, use of any such terms should not be taken to limit the spirit and scope of embodiments of the present disclosure.

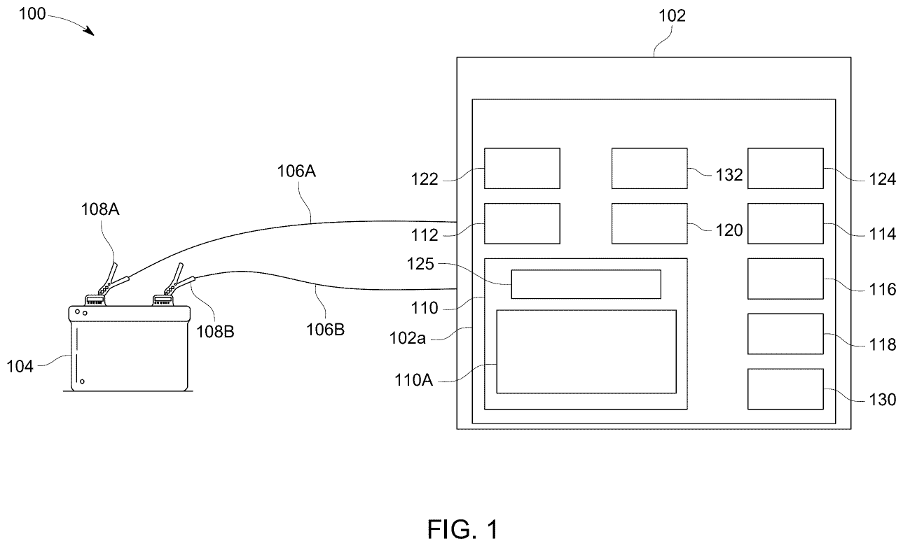

The embodiments are described herein for illustrative purposes and are subject to many variations. It is understood that various omissions and substitutions of equivalents are contemplated as circumstances may suggest or render expedient but are intended to cover the application or implementation without departing from the spirit or the scope of the present disclosure. Further, it is to be understood that the phraseology and terminology employed herein are for the description and should not be regarded as limiting. Any heading utilized within this description is for convenience only and has no legal or limiting effect. Referring to FIG. 1-FIG. 4, a brief description concerning the various components of the present disclosure will now be briefly discussed. Reference will be made to the figures showing various embodiments of fire alarm battery load tester.

FIG. 1 is a diagram that illustrates an exemplary network environment 100 in which a fire alarm battery load tester 102 is implemented, in accordance with an embodiment of the disclosure. With reference to FIG. 1, there is shown the network environment 100 that may include a fire alarm battery load tester 102 to test a fire alarm battery 104, a first test lead 106A, a second test lead 106B, a first connector 108A, and a second connector 108B.

In an embodiment, the fire alarm battery 104 may correspond to a device configured to provide backup power to the fire alarm system, thereby ensuring the fire alarm system remains operational during power outages. Further, the fire alarm battery 104 may be designed to supply necessary voltage and current, thereby ensuring reliability and functionality of the fire alarm system. Additionally, the fire alarm battery 104 may supply voltage and current to sensors, detectors, and control panels associated with the fire alarm system. thereby ensuring reliability and functionality of the fire alarm system. Example of the fire alarm battery 104 may include, but is not limited to, a sealed lead-acid battery, lithium-ion battery, and a nickel-cadmium battery. In an embodiment, the fire alarm system may employ two 12 volt lead-acid batteries for the equivalent of 24 volts or a single 24 volt battery. For example, the 12 volt rechargeable lead-acid battery may have a capacity range of 1 Ah (ampere hours) to more than 100+Ah.

The fire alarm battery load tester 102 may correspond to a device that may be configured to evaluate performance and condition of the fire alarm battery 104 which may be a 12 volt battery or a 24 volt battery. The fire alarm battery load tester 102 may apply a load to the fire alarm battery 104 and measures a response of the fire alarm battery based on the applied load. This facilitates to determine reliability of the fire alarm battery 104 during emergency conditions. In an example, the fire alarm battery load tester 102 may test capacity and condition of the fire alarm battery 104 by applying the simulated load and measuring voltage and current response, thereby helping to assess the ability of the fire alarm battery 104 to deliver necessary power under critical real-world operating conditions. The simulated load applied to the fire alarm battery 104 may mimic the operational conditions of the fire alarm system. This process may help in determining, for example, but not limited to, a charge state of the fire alarm battery 104, capacity of the fire alarm battery 104, and overall health of the fire alarm battery 104.

The fire alarm battery load tester 102 includes a housing 102a defining an interior space. The housing 102a may correspond to an outer case or an outer shell associated with the fire alarm battery load tester 102. The interior space may correspond to a space inside the housing 102a associated with the fire alarm battery load tester 102. In an exemplary embodiment, the housing 102a may be made of materials, for example, but not limited to, plastic, metal or composite materials. The housing 102a supports one or more components of the fire alarm battery load tester 102, for example, an electronic circuitry 110 including one or more electronic components 110A, a fan 112, a test switch 114, a display 116, an indicator 118, a timer 120, a communication device 122, at least one temperature sensor 124, etc.

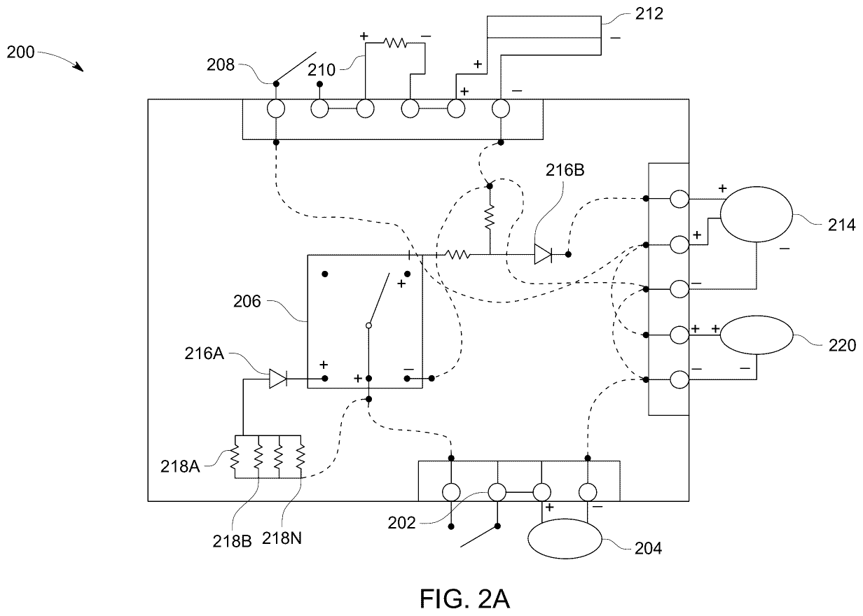

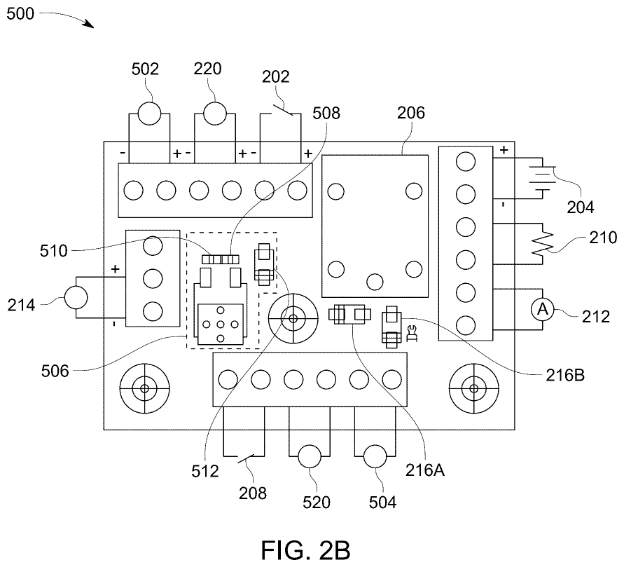

The electronic circuitry 110 may correspond to an arrangement of the one or more electronic components 110A interconnected to perform a specific operation. Specifically, the electronic circuitry 110 may be operable to test the fire alarm battery 104. Further, the one or more electronic components 110A may include, but are not limited to one or more resistors, one or more diodes, a relay, and integrated circuits. Details associated with the interconnection of the one or more electronic components 110A housed within the electronic circuitry 110, are provided for example, in FIG. 2A and FIG. 2B. In the embodiment, the tester 102 includes a 5 Ohm internal resistor 125 which is electrically connected with the fire alarm battery to measure/detect electrical parameters, for example, voltage and amperage, of the fire alarm battery. In the embodiment, the 5 Ohm resistor 125 is a 200 watt power resistor.

In an embodiment, the fan 112 may correspond to a cooling fan to cool the electronic circuitry 110 and any other electrical or electronic component of the fire alarm battery load tester 102. Specifically, the fan 112 in the fire alarm battery load tester 102 may correspond to a mechanical device used to dissipate heat generated by the one or more electronic components 110A housed within the electronic circuitry 110 while in operation, thereby preventing overheating and ensuring reliable operations. For example, the fan 112 may move air across heat generating components to enhance heat transfer and maintain safe operating temperatures. Examples of the fan 112 may include, but not limited to, axial fans and centrifugal fans. In some embodiments, the fan 112 is activated in response to the activation of the fire alarm battery load tester 102. In some embodiments, the fan 112 is activated in response to a temperature inside the housing or the electronic circuitry being above than a threshold temperature. The temperature inside the housing or the temperature of the electronic circuitry 110 is measured by at least one temperature sensor 124. Further, the fire alarm battery load tester 102 may include a switch adapted to manipulated by a user to control the fan 112, for example, switch on and switch off the fan.

In an embodiment, the display 116 associated with the fire alarm battery load tester 102 may be configured to display measurement values associated with the performance of the fire alarm battery 104. Example of the display 116 may include, but is not limited to, a Liquid Crystal Display (LCD), a Light Emitting Diode (LED)-based display, and the like. In an exemplary embodiment, the display 116 of the fire alarm battery load tester 102 indicates one or more electrical parameters, for example, a magnitude of the current and/or the voltage associated with the fire alarm battery 104. The display 116 may facilitate an accurate and real-time monitoring of the performance of the fire alarm battery 104, thereby allowing user to identify any issues or problems with respect to the fire alarm battery 104. In an exemplary embodiment, the user may be, but not limited to, a fire alarm technician.

In an embodiment, the user (for example, the fire alarm technician) may connect the fire alarm battery load tester 102 to the fire alarm battery 104 using the set of test leads. The test leads may refer to flexible, insulated wires used to connect the fire alarm battery load tester 102 to the terminals of the fire alarm battery 104 (for example, the device under test) to measure one or more electrical parameters of the fire alarm battery 104. Examples of the one or more electrical parameters may include, but are not limited to a voltage, a current, or resistance. Typically, the test leads may have connectors or probes at each end to ensure a secure, and reliable connection. For example, the connectors may be alligator clips (for example the first connector 108A, and the second connector 108B) that may facilitate to connect the fire alarm battery load tester 102 to the terminals of the fire alarm battery 104, thereby ensuring a secure connection and preventing any accidental disconnection during testing of the fire alarm battery 104.

In an embodiment, the first connector 108A may be attached to the first test lead 106A and the second connector 108B may be attached to the second test lead 106B. In an exemplary embodiment, the user may connect the first connector 108A to a first terminal of the fire alarm battery 104, and the second connector 108B to a second terminal of the fire alarm battery 104. In an embodiment, the set of test leads (such as the first test lead 106A and the second test lead 106B) may be color coded to match the terminals of the fire alarm battery 104. In an exemplary embodiment, each of the set of test leads may be color coded in a particular color for example, but not limited to, a red color test lead for positive, and a black color test lead for negative. The color coding may ensure that the red color test lead is connected to a positive terminal of the fire alarm battery 104, and the black test lead is connected to a negative terminal of the fire alarm battery 104. Further, the set of test leads may be designed to be flexible and of a pre-defined length to ensure that the set of test leads may reach the terminals of the fire alarm battery 104 without any strain. The pre-defined length of the set of test leads may be for example, but not limited to, 30 centimeter (cm), 50 cm, 100 cm, 1 meter, and the like. In an embodiment, the set of test leads (such as the first test lead 106A and the second test lead 106B) may be insulated to prevent electrical shock or short circuits during testing. In an example, the set of test leads may be insulated using rubber or silicone to provide flexibility and electrical insulation.

The proposed fire alarm battery load tester 102 may correspond to a handheld battery load tester. For example, a portable device with connectors (for example, the first connector 108A, the second connector 108B) for attaching to the battery terminals, an internal load resistor, and the display 116 for voltage and current readings. In operation, the fire alarm battery load tester 102 may be connected with the fire alarm battery 104 using the set of test leads and the alligator clips. Thereafter, test switch 114 is operated/pressed to complete an electrical circuit of the fire alarm battery load tester 102 and route the current drawn from the fire alarm battery 104 through the one or more electronic components 110A (for example, internal load resistor housed inside the housing 102a). This may simulate the actual load conditions that the fire alarm battery 104 may face in a fire alarm system. In an embodiment, the fire alarm battery load tester 102 may include a timer 120 that is activated upon actuation of the test switch 114 or the power switch, and is configured to monitor a time elapsed since the activation of the test switch 114. The test switch 114 is coupled with the timer 120, and is reset when the timer 120 indicates an elapse of the predefined time from the actuation of the test switch 114. Accordingly, the electronic circuitry 110 is electrically disconnected from the fire alarm battery 104 if the fire alarm battery load tester remains idle for the predefined time duration.

In some embodiments, the fire alarm battery load tester 102 may share the measured data to a smart phone or any other similar device to enable a user to access the measured data on the smart phone. The communication device 122 facilitates a communication and data exchange between the fire alarm battery load tester 102 and the smart phone. In an embodiment, the communication device 122 is a short range communication device, for example, BLUETOOTH™ device, a near field communication device, or a WiFi. Although the communication device 122 is contemplated as the short range communication device, it may be envisioned that the communication device 122 may be a long range communication device to enable a transfer of data from the fire alarm battery load tester 102 to a remote commuting device, for example, a remotely located server.

In an embodiment, the fire alarm battery load tester 102 further includes the reverse polarity protector 130 to prevent damages if the fire alarm battery 104 may be connected incorrectly by the user, thus ensuring longevity and safety of the fire alarm battery load tester 102 and the user. The reverse polarity occurs when the positive terminal and the negative terminal of the fire alarm battery 104 are connected to the opposite terminal of the fire alarm battery load tester 102. For example, if the red test lead (such as the first test lead 106A) that is supposed to be connected to the positive terminal of the fire alarm battery 104 is connected to the negative terminal of the fire alarm battery 104 and the black test lead (such as the second test lead 106B) that is supposed to be connected to the negative terminal of the fire alarm battery 104 is connected to the positive terminal of the fire alarm battery 104, in this scenario, the reverse polarity may occur. The reverse polarity protector 130 interrupts the electric circuit of the fire alarm battery load tester 102 and thereby prevents a flow of electric current to the electronic circuitry 110 of the fire alarm battery load tester 102, thereby protecting the components of the fire alarm battery load tester 102. In the embodiment, the first reverse polarity protector 130 is a reverse protection polarity protection circuitry. However, in some embodiments, the reverse polarity protector 130 may be a fuse. The reverse polarity protector 130 also protects the user from hazardous arc flash conditions. The hazardous arc flash may be caused by an accidental short circuit in the electronic circuitry 110 of the fire alarm battery load tester 102.

The fire alarm battery load tester 102 may include an indicator 118 that may get triggered when the reverse polarity occurs during testing, thus notifying the user. For example, the indicator 118 may provide a visual or an audio signal to convey information about the status of the circuit. Examples of the visual indicator include, but are not limited to LED indicator, and the audio indicators include, but are not limited to alarms and buzzers.

In some embodiments, the fire alarm battery load tester 102 may include a shutdown mechanism 132, for example, a fuse, to electrically disconnect the fire alarm battery 104 from the fire alarm battery load tester 102 when a delinquency of fault in the electrical or electronic circuit of the fire alarm batter load tester 102. Also, the shutdown mechanism 132, in some embodiments, shut-off all the electrical and electronic components, for example, fan 112, the communication device 122, the display 116, the indicator 118, etc., of the fire alarm battery load tester 104 upon an occurrence of the electrical fault.

While in operation, when the power switch is turned-on of the fire alarm battery load tester 102, the fan 112 turns on instantaneously. Thereafter, the test switch is turned on, and the fire alarm battery load tester 102 may start to draw current from the fire alarm battery 104 to test the fire alarm battery 104 under load condition. Further, the display 116 may indicate a measurement of a voltage and current during the test, thereby providing real-time stand-by data on the performance of the fire alarm battery 104 under the load as listed in the CAN/ULC s536-19 and CAN/ULC s537-19. The real-time stand-by data may include the current data and the voltage data associated with the fire alarm battery 104 during the test. The current data and the voltage data may be crucial for determining whether the fire alarm battery 104 meets the necessary standards. In an embodiment, while the one or more electronic components 110A (or the internal load resistor) may be simulating or exceeding the load conditions. In an embodiment, the internal load resistor may be housed inside of the fire alarm battery load tester 102 may be used to simulate a specific electrical load for testing the performance of the fire alarm battery 104. The internal load resistor may act as a substitute for the components of the fire alarm system such as, but not limited to, sensors, lights, and sounders. The internal load resistor may draw a similar amount of current as the fire alarm system may draw during its operation. The internal load resistor may help in evaluating the performance of the fire alarm battery 104 under realistic conditions.

Further, the fire alarm battery load tester 102, with its known resistance may allow for accurate measurement of the current that is being supplied by the fire alarm battery 104. By knowing the value of the internal load resistor and measuring voltage drop across the internal load resistor, the fire alarm battery load tester 102 may measure the current using Ohm's law

$$V ( voltage ) = I ( current ) \times R ( resistance ) .$$

In an embodiment, the voltage drop across the internal load resistor may be monitored to see how efficiently the fire alarm battery 104 maintains its voltage under the load. As the internal load resistor may convert electrical energy from the fire alarm battery 104 into heat, the fan 112 may dissipate the heat into the environment to ensure proper heat management. This may prevent overheating, thus keeping the testing environment safe and maintaining the accuracy of the test. In an exemplary embodiment, when the fire alarm battery load tester 102 may perform testing of the fire alarm battery 104, the one or more electronic components 110A within the fire alarm battery load tester 102 may start to heat up. In such a scenario, the fan 112 may ensure that the fire alarm battery load tester 102 may operate within a safe temperature range preventing overheating, that may cause damage to the components of the fire alarm battery load tester 102 or cause fire hazard. Also, the overheat shutdown switch/mechanism is activated to stop the flow of current to the fire alarm battery load tester 102 if the temperature inside the housing or any components of the fire alarm battery load tester reaches above a predefined threshold temperature.

Typically, battery capacity of the fire alarm battery 104 may be tested based on full system load on a regular basis using the fire alarm battery load tester 102, and results may be constantly recorded. In an exemplary embodiment, the fire alarm battery load tester 102 may use constant load technology to simulate power requirements of the fire alarm system, thus providing a complete test of the condition of the fire alarm battery 104. Further, the fire alarm battery load tester 102 may be configured to test the fire alarm battery 104 with voltage level that may be, but not limited to, 6 volts, 12 volts, and 24 volts. In an exemplary embodiment, the fire alarm battery load tester 102 may be a 24 volts fire alarm battery load tester. In an embodiment, the fire alarm battery load tester 102 may be configured to meet requirements of CAN/ULC s536-19 and CAN/ULC s537-19 for regular testing and maintenance of the fire alarm battery 104. Further, a regular maintenance, inspection, and replacement of the fire alarm battery 104 are crucial to ensure the system operates effectively and safely.

FIG. 2A illustrates an exemplary circuit diagram 200 of the fire alarm battery load tester 102 of FIG. 1, in accordance with an embodiment of the disclosure. FIG. 2A is explained in conjunction with FIG. 1. In FIG. 2A there is shown the circuit diagram 200 of the electronic circuity 110 that includes the electronic components 110A such as a power switch 202, a battery 204 (for example the fire alarm battery 104), a relay 206, a test switch 208, an internal load resistor 210, an ammeter 212, a voltmeter 214, a fan 220 (for example the fan 112), one or more diodes (such as 216A, 216B), and one or more resistors (such as 218A, 218B, up to 218N).

It is to be noted that one or more resistors (such as 218A, 218B, up to 218N) may include 4 resistors connected in parallel configuration to create a specific load, as shown in the circuit diagram 200. In an exemplary scenario, the one or more resistors may include 1 resistor to create a specific load. It may be understood by one skilled in the art that changes in the circuitry may be equivalently used in the fire alarm battery load tester 102, without deviating from the scope of the present disclosure.

In an exemplary embodiment, the electronic components 110A of the electronic circuitry 110 may be interconnected by conductive pathways, such as printed circuit boards, wires and traces. In operation, once the user may connect the battery 204 (such as fire alarm battery 104 of FIG. 1) to the terminal of the fire alarm battery load tester 102, the power switch 202, and the test switch 208 may be turned on by the user of the fire alarm battery load tester 102. Upon turning on both the power switch 202, and the test switch 208, the fan 220 may be activated. This may complete the circuit, thereby initiating the testing of the battery 204. The battery 204 may power the fire alarm battery load tester 102 by passing the current through the one or more wires or conductive pathways of the printed circuit board (PCB) that may be connected via the relay 206. In an embodiment, the relay 206 may be an electromechanical switch that may be operated by a small electric current, that may turn on or off a much larger electric current. The relay 206 may be of different types such as, but not limited to. electromechanical relay or solid-state relay. The characteristics of the relay 206 may be, for example, but not limited to, 10 amperes and 12 Volts Direct Current (VDC).

In an embodiment, the relay 206 may act as an electrically operated switch. When the relay 206 may be activated, it may connect the battery 204 to the internal load resistor 210, allowing the current to flow through the internal load resistor 210. In a scenario, when the relay 206 may be deactivated, it may disconnect the battery 204 from the internal load resistor 210, thereby stopping the flow of the current.

The internal load resistor 210 (the resistor) may be, such as, but not limited to, 5-Ohm resistor with power capacity of 250 Watts. In an embodiment, the current may flow through the internal load resistor 210 simulating the operational load conditions of the fire alarm system. The current flowing through the internal load resistor 210 may be measured by the ammeter 212. The measured current may be indicative of ability of the battery 204 to supply power under load conditions. In an exemplary embodiment, the ammeter may be connected in series with the internal load resistor 210. Similarly, the voltage across the battery 204 may be measured by the voltmeter 214. The measured voltage may be indicative of how the battery 204 may maintain its voltage under the load conditions.

In an embodiment, when the internal load resistor 210 may dissipate heat while in operation. In such a scenario, the fan 220 may facilitate to prevent overheating of the electronic components 110A of the electronic circuitry 110. Further, the one or more diodes (such as 216A, and 216B) may be configured to protect the fire alarm battery load tester 102 against the reverse polarity. In an exemplary embodiment, if the battery 204 may be connected incorrectly, the one or more diodes (such as 216A, and 216B) may block the incorrect flow of the current, preventing damage to the electronic components 110A of the electronic circuitry 110. The one or more diodes may ensure that the current flows only in the intended direction. The characteristics of each of the one or more diodes (such as 216A, and 216B) may be, for example, but not limited to, 20 volts 1 ampere diode.

In an exemplary embodiment, the test switch 208 may be connected to the battery 204 via the one or more resistors (such as 218A, 218B, up to 218N). Each of the one or more resistors may correspond, but not limited to, 1 kiloohm (KΩ), ¼ watt (W) resistors.

Referring to FIG. 2B, another circuit diagram 500 of the fire alarm battery load tester 102 of FIG. 1 is shown, according to some example embodiment of the disclosure. The circuit diagram 500 is similar to the circuit diagram 200 except that one or more resistors 218A, 218N, up to 218N are omitted from the circuit diagram 500. Moreover, the circuit diagram 500 additionally includes a timer 502, a overheat shutdown switch 504, a power regulating integrated circuit 506 including diodes 512 and capacitors 508, 510, a time delinquency shutdown switch 520. The time delinquency shutdown mechanism/switch 520 is configured to shut down the fire alarm battery load tester 102 upon detecting no activity of the tester 102 for a predefined time duration. The time duration may be monitored by the timer 502.

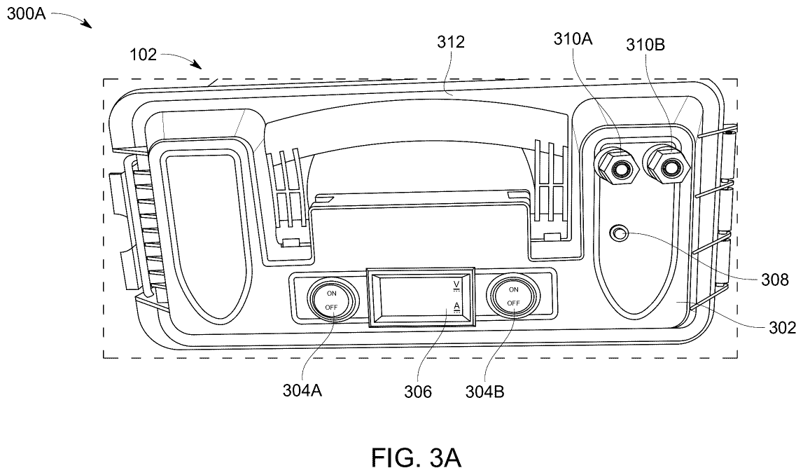

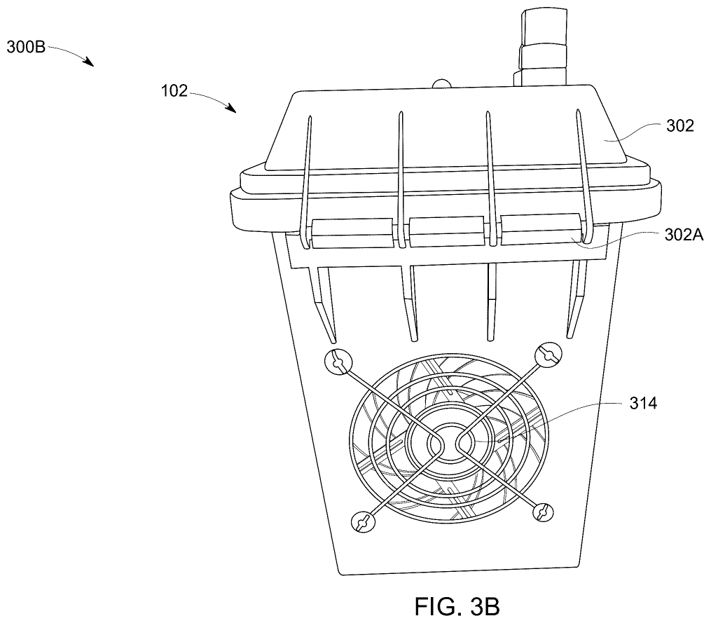

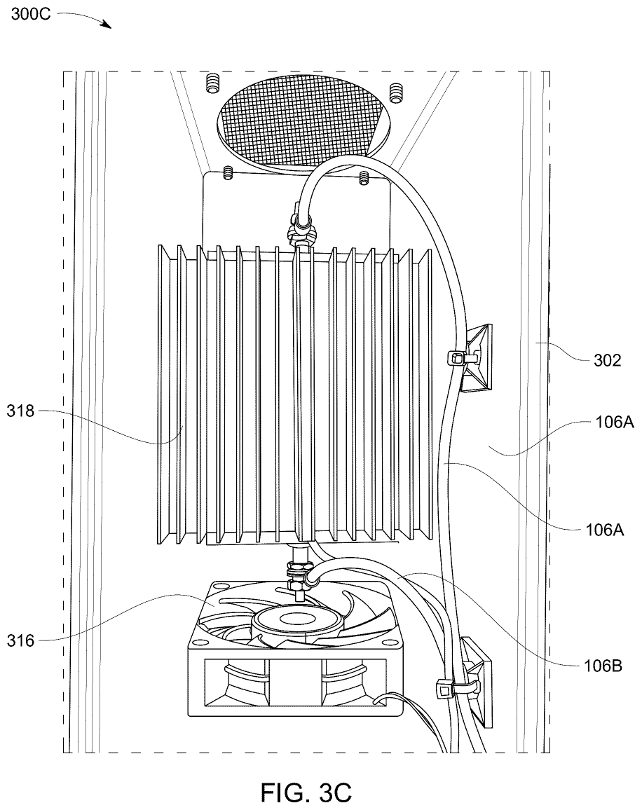

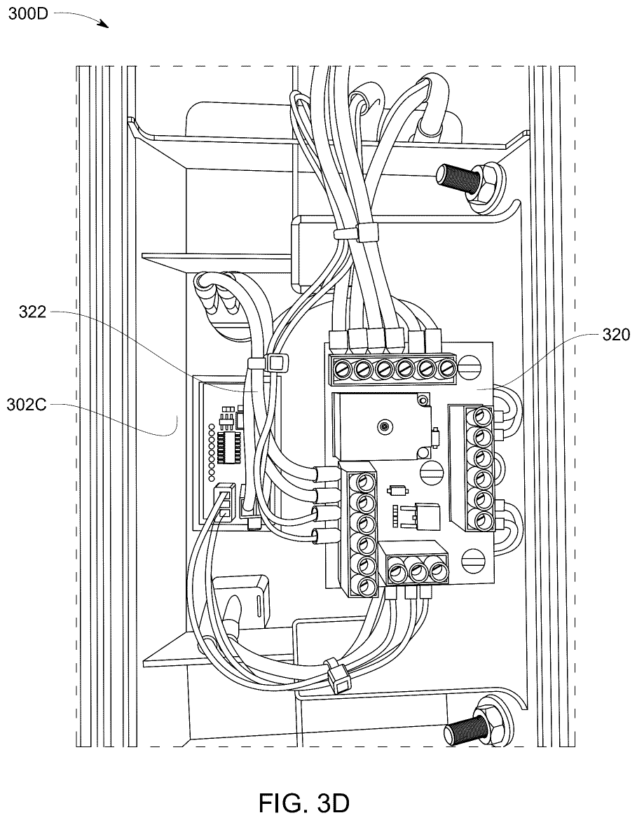

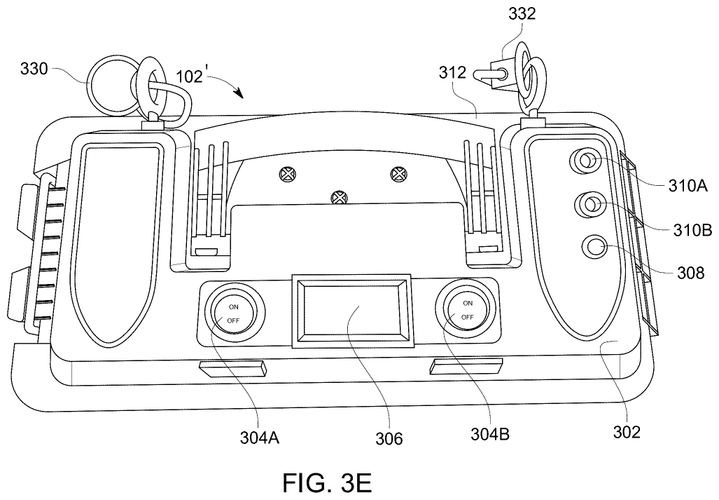

FIG. 3A illustrates an exemplary front view 300A of the fire alarm battery load tester 102, in accordance with the disclosure. FIG. 3A is explained in conjunction with FIG. 1 and FIG. 2. In FIG. 3A there is shown the front view of the fire alarm battery load tester 102 that may include a housing 302 defining an interior space to enclose an electronic circuitry (as shown in FIGS. 3C-3D) operable to test the fire alarm battery 104. The housing 302 may further include a switch 304B to control a flow of electric current from the fire alarm battery to the electronic circuitry, a display 306 to display the one or more electrical parameters associated with the fire alarm battery 104, and an indicator 308 to indicate a reverse polarity connection of the fire alarm battery 104.

There is further shown a switch 304A i.e., test switch 304A adapted to be manipulated by a user to direct current from the fire alarm battery through 5 Ohm resistor. As the current passes through the 5 Ohm resistor, the internal circuitry measures and displays the voltage and current of the fire alarm battery 104 under test load. Further, the terminals (for example, a first terminal 310A and a second terminal 310B) to operably connect the fire alarm battery load tester 102 to the fire alarm battery 104 using the set of test leads (106A, and 106B) are also shown. The first terminal 310A may be red in color that may be connected to the positive terminal of the fire alarm battery 104, and the second terminal 310B may be black in color may be connected to the negative terminal of the fire alarm battery 104.

In an embodiment, the indicator 308 may indicate whether the connection of the fire alarm battery load tester 102 with the fire alarm battery 104 is correct or incorrect. In a scenario where the connection is incorrect, the indicator 308 may be triggered to indicate the reverse polarity. In an example, the indicator 308 may blink or glow constantly to indicate the reverse polarity connection. Further, the fire alarm battery load tester 102 may further include a handle 312, thereby making the fire alarm battery 104 portable, handheld and easy to carry.

It is to be noted that the fire alarm battery load tester 102 is an example of the fire alarm battery load tester 102 as described in FIG. 1. Similarly, the switch 304A, the display 306, and the indicator 308 are examples of the test switch 114, the display 116 and the indicator 118 of the FIG. 1, respectively.

FIG. 3B illustrates an exemplary side view 300B of the fire alarm battery load tester 102, in accordance with the disclosure. FIG. 3B is explained in conjunction with FIG. 1, FIG. 2, and FIG. 3A. In FIG. 3B there is shown the side view 300B the fire alarm battery load tester 102. The housing 302 further includes the fan 112 to cool the electronic circuitry 110. The fan 112 may be utilized to dissipate the heat generated by the one or more electronic components 110A to the environment, thereby cooling the fire alarm battery load tester 102 during the testing of the fire alarm battery 104.

As shown FIG. 3B, the fire alarm battery load tester 102 includes a fan grill 314 that covers the fan 112 to prevent dust, dirt, and other debris from entering the fan, thereby causing damage or reducing its performance. It also protects the user from the fan 112.

In an example, the housing 302 may correspond to a hinged box including a hinge and a securing mechanism. As shown, on one edge of the housing 302, hinges 302A may be connected, and on an opposite edge of the housing 302 the latch or any other securing mechanism may be connected. When the securing mechanism is released, the box may open revealing the interior space of the housing 302 including an upper lid and a bottom container.

In another example, the housing 302 may not have hinges and may be opened upright. Further, upon opening the housing 302 of the fire alarm battery load tester 102, the user may be able to access the interior space enclosing the electronic circuity and other components of the fire alarm battery load tester 102.

FIG. 3C illustrates an exemplary internal view 300C of the housing 302 enclosing a fan 316 of the fire alarm battery load tester 102, in accordance with the disclosure. FIG. 3C is explained in conjunction with FIG. 1, FIG. 2, FIG. 3A, and FIG. 3B. It is to be noted that the fan 316 is an example of the fan 112 of FIG. 1.

In FIG. 3C there is shown the internal view 300C of the housing 302 of the fire alarm battery load tester 102. There is shown an interior space including a bottom container 302B of the housing 302 to enclose the fan 316, the set of test leads (106A, and 106B) along with connectors (108A, and 108B), and a metal extruded plate 318 (such as a heat sink) to provide heat dissipation and support to the electronic circuitry 110.

The metal extruded plate 318 may correspond to the heat sink to facilitate further heat dissipation in the fire alarm battery load tester 102. In an example, the metal extruded plate 318 may be an aluminum extruded plate configured to dissipate the heat away from the internal load resistor and other components of the fire alarm battery load tester 102 to prevent overheating. Further, the metal extruded plate 318 may dissipate the heat from the one or more electronic components 110A, thereby maintaining a stable operating temperature within the fire alarm battery load tester 102. In an exemplary embodiment, the operating temperature may be pre-defined. In an embodiment, the metal extruded plate 318 may be made of components with high conductivity such as, but not limited to, aluminum, or copper. Further, the fan 316 housed within the interior space of the bottom container 302B of the housing 302 of the fire alarm battery load tester 102 may extract heat from the metal extruded plate 318 and dissipate the heat in surrounding air, thus maintaining the operating temperature within the fire alarm battery load tester 102.

FIG. 3D illustrates another exemplary internal view 300D of the housing 302 enclosing the electronic circuitry 110 of the fire alarm battery load tester 102, in accordance with the disclosure. FIG. 3D is explained in conjunction with FIG. 1, FIG. 2, FIG. 3A, FIG. 3B, and 3C. In FIG. 3D there is shown the interior space including an upper lid 302C of the housing 302 to enclose the electronic circuitry 110.

FIG. 3E illustrates another example of a fire alarm battery load tester 102′ that is similar to the front view 300A of the fire alarm battery load tester 102 shown in FIG. 3A except that the fire alarm battery load tester 102′ includes at least one magnetic connector, for example, two magnetic connector 330, 332 to facilitate a magnetic coupling of the fire alarm battery load tester 102′ to a fire alarm chassis to enable a mounting of the fire alarm battery load tester 102′ to the fire alarm chassis.

There is further shown a Printed circuit board (PCB) 320 assembly including wiring 322 and the one or more electronic components 110A of the electronic circuitry 110. Details of the one or more electronic components of the electronic circuitry and connections therewith are provided for example, in FIGS. 1 and 2.

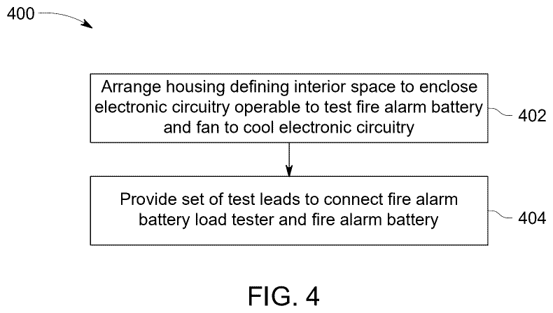

FIG. 4 is a flowchart 400 that illustrates an exemplary method for fabricating the fire alarm battery load tester 102, in accordance with an embodiment of the disclosure. FIG. 4 is explained in conjunction with the FIGS. 1, 2, 3A, 3B, and 3C. The exemplary method may start at 402.

At 402, the housing 102a defining an interior space of the fire alarm battery load tester 102 may be arranged. The housing 102a may define the interior space to enclose the electronic circuitry 110 operable to test the fire alarm battery 104 and the fan 112 to cool the electronic circuitry 110. The electronic circuitry 110 may be configured to measure the one or more electrical parameters of the fire alarm battery 104.

In an embodiment, the fire alarm battery load tester 102 may further include the test switch 114 to control the flow of the electric current from the fire alarm battery 104 to the electronic circuitry 110. Further, the fire alarm battery load tester 102 may include the display 116 to display the one or more electrical parameters of the fire alarm battery 104. In an embodiment, the one or more electrical parameters may include the voltage of the fire alarm battery 104, and the current of the fire alarm battery 104. Further, the fire alarm battery load tester 104 may include the indicator 118 to indicate the reverse polarity of the fire alarm battery 104. In an embodiment, the electronic circuitry 110 includes one or more electronic components 110A housed thereon. The one or more electronic components 110A may include at least one or more resistors (such as 218A, 218B, 218N), one or more diodes (such as 216A, and 216B), and a relay 206.

At 404, at least two test leads may be provided to connect the fire alarm battery load tester 102 and the fire alarm battery 104.

Alternatively, the fire alarm battery load tester 102 may comprise means for performing each of the operations described above. In this regard, according to an example embodiment, examples of means for performing operations may comprise, for example, the processor and/or a device or circuit for executing instructions or executing an algorithm for processing information as described above.

Many modifications and other embodiments of the inventions set forth herein will come to mind to one skilled in the art to which these inventions pertain having the benefit of the teachings presented in the foregoing descriptions and the associated drawings. It is to be understood that the inventions are not to be limited to the specific embodiments disclosed and that modifications and other embodiments are intended to be included within the scope of the appended claims. Moreover, although the foregoing descriptions and the associated drawings describe example embodiments in the context of certain example combinations of elements and/or functions, it should be appreciated that different combinations of elements and/or functions may be provided by alternative embodiments without departing from the scope of the appended claims. In this regard, for example, different combinations of elements and/or functions than those explicitly described above are also contemplated as may be set forth in some of the appended claims. Although specific terms are employed herein, they are used in a generic and descriptive sense only and not for purposes of limitation.

1. A fire alarm battery load tester, comprising:
a housing defining an interior space;
an electronic circuitry arranged inside the housing and operable to test a fire alarm battery;
a set of test leads to connect the electronic circuitry to the fire alarm battery to direct an electric current from the fire alarm battery to the electronic circuitry to enable a measurement of one of more electrical parameters of the fire alarm battery; and
a fan coupled to the housing cool the electronic circuitry.

2. The fire alarm battery load tester of claim 1 comprises a test switch to control a flow of electric current from the fire alarm battery to the electronic circuitry.

3. The fire alarm battery load tester of claim 1 comprises a display to show the one or more electrical parameters of the fire alarm battery measured by the electronic circuitry.

4. The fire alarm battery load tester of claim 3, wherein the one or more electrical parameters includes a voltage of the fire alarm battery and a current of the fire alarm battery.

5. The fire alarm battery load tester of claim 1, wherein the electronic circuitry includes one or more electronic components, wherein the one or more electronic components includes at least one of one or more resistors, one or more diodes, or one or more relays.

6. The fire alarm battery load tester of claim 1 comprises an indicator to indicate a reverse polarity of the fire alarm battery.

7. The fire alarm battery load tester of claim 1 further comprises a communication device to facilitate a sharing of data measured by the electronic circuitry to a smart phone.

8. The fire alarm battery load tester of claim 7, wherein the communication device is a short range communication device.

9. The fire alarm battery load tester of claim 1 comprises a reverse polarity protector to electrically disconnect the fire alarm battery from the electronic circuitry in response to reverse polarity connection of the fire alarm battery with the fire alarm battery load tester.

10. The fire alarm battery load tester of claim 1 further comprises a shutdown mechanism adapted to shut down the fire alarm battery load tester in response to an occurrence of a fault in the fire alarm battery load tester.

11. The fire alarm battery load tester of claim 1 further comprises at least one magnetic connector to facilitate a magnetic coupling and mounting of the fire alarm battery load tester to a fire alarm chassis.
